(19) United States
(12) Patent Application Publication
(10) Pub. No.: US 2025/0393275 A1
(43) Pub. Date: Dec. 25, 2025

(54) SILICON CARBIDE EPITAXIAL SUBSTRATE AND METHOD OF MANUFACTURING SILICON CARBIDE SEMICONDUCTOR DEVICE

(71) Applicant: SUMITOMO ELECTRIC INDUSTRIES, LTD., Osaka (JP)

(72) Inventors: Hideyuki HISANABE, Osaka (JP); Taro ENOKIZONO, Osaka (JP); Tetsuro KONDO, Osaka (JP)

(73) Assignee: SUMITOMO ELECTRIC INDUSTRIES, LTD., Osaka (JP)

(21) Appl. No.: 18/880,087

(22) PCT Filed: Jul. 7, 2023
(86) PCT No.: PCT/JP2023/025277

§ 371 Date: Dec. 30, 2024

(30) Foreign Application Priority Data
Jul. 20, 2022 (JP) 2022-115800

(51) Int. Cl. H10D 62/832; H10D 12/00; H10D 30/66; H10D 62/40

(52) U.S. Cl. CPC H10D 62/8325; H10D 62/405; H10D 12/481; H10D 30/668

(57) ABSTRACT

A silicon carbide epitaxial substrate has a silicon carbide substrate and a silicon carbide epitaxial layer. The silicon carbide epitaxial layer has a first main surface. A recess is formed in the first main surface. As viewed in a direction perpendicular to the first main surface, an outer shape of the recess is a triangular shape. A depth of the recess in the direction perpendicular to the first main surface is 100 nm or more. A length of the recess in a direction obtained by projecting a <11-20> direction onto the first main surface is 80 μm or less. An area density of the recesses in the first main surface is 0.1/cm² or less. A polytype of silicon carbide of a bottom surface of the recess is different from a polytype of silicon carbide of the silicon carbide epitaxial layer.

### TECHNICAL FIELD

The present disclosure relates to a silicon carbide epitaxial substrate and a method of manufacturing a silicon carbide semiconductor device. The present application claims priority based on Japanese Patent Application No. 2022-115800 filed on Jul. 20, 2022. The entire contents of the Japanese Patent Application are incorporated herein by reference.

### BACKGROUND ART

Japanese Patent Laying-Open No. 2011-121847 (PTL 1) discloses a silicon carbide epitaxial wafer in which a density of a defect having a triangular shape in a surface of a silicon carbide epitaxial layer is 1/cm² or less.

### CITATION LIST

### Patent Literature

PTL 1: Japanese Patent Laying-Open No. 2011-121847

### SUMMARY OF INVENTION

A silicon carbide epitaxial substrate according to the present disclosure includes a silicon carbide substrate and a silicon carbide epitaxial layer. The silicon carbide epitaxial layer is located on the silicon carbide substrate. The silicon carbide epitaxial layer has a first main surface. A recess is formed in the first main surface. As viewed in a direction perpendicular to the first main surface, an outer shape of the recess is a triangular shape. A depth of the recess in the direction perpendicular to the first main surface is 100 nm or more. A length of the recess in a direction obtained by projecting a <11-20> direction onto the first main surface is 80 μm or less. An area density of the recess in the first main surface is 0.1/cm² or less. A polytype of silicon carbide of the bottom surface of the recess is different from a polytype of silicon carbide of the silicon carbide epitaxial layer.

### BRIEF DESCRIPTION OF DRAWINGS

FIG. 1 is a schematic plan view showing a configuration of a silicon carbide epitaxial substrate according to the present embodiment.

FIG. 2 is a schematic cross sectional view along a line II-II of FIG. 1.

FIG. 3 is an enlarged schematic plan view of a region III in FIG. 1.

FIG. 4 is a schematic cross sectional view along a line IV-IV of FIG. 3.

FIG. 5 is a partial schematic cross sectional view showing a configuration of a manufacturing apparatus for the silicon carbide epitaxial substrate.

FIG. 6 is a schematic diagram showing a relation between a time and a silane flow rate with respect to a temperature.

FIG. 7 is a flowchart schematically showing a method of manufacturing a silicon carbide semiconductor device according to the present embodiment.

FIG. 8 is a schematic cross sectional view showing a step of forming a body region.

FIG. 9 is a schematic cross sectional view showing a step of forming a source region.

FIG. 10 is a schematic cross sectional view showing a step of forming a trench in a first main surface of a silicon carbide epitaxial layer.

FIG. 11 is a schematic cross sectional view showing a step of forming a gate insulating film.

FIG. 12 is a schematic cross sectional view showing a step of forming a gate electrode and an interlayer insulating film.

FIG. 13 is a schematic cross sectional view showing a configuration of the silicon carbide semiconductor device according to the present embodiment.

### DETAILED DESCRIPTION

### Problem to be Solved by the Present Disclosure

An object of the present disclosure is to provide a silicon carbide epitaxial substrate and a method of manufacturing a silicon carbide semiconductor device so as to attain improved yield of the silicon carbide semiconductor device.

### Advantageous Effect of the Present Disclosure

According to the present disclosure, it is possible to provide a silicon carbide epitaxial substrate and a method of manufacturing a silicon carbide semiconductor device so as to attain improved yield of the silicon carbide semiconductor device.

### Description of Embodiments

First, an overview of an embodiment of the present disclosure will be described. Regarding crystallographic indications in the present specification, an individual orientation is represented by [ ], a group orientation is represented by < >, and an individual plane is represented by ( ), and a group plane is represented by { }. In addition, a negative index is supposed to be crystallographically indicated by putting “-” (bar) above a numeral, but is indicated by putting the negative sign before the numeral in the present specification.

(1) A silicon carbide epitaxial substrate 100 according to the present disclosure includes a silicon carbide substrate 30 and a silicon carbide epitaxial layer 40. Silicon carbide epitaxial layer 40 is located on silicon carbide substrate 30. Silicon carbide epitaxial layer 40 has a first main surface 1. A recess 29 is formed in first main surface 1. As viewed in a direction perpendicular to first main surface 1, an outer shape of recess 29 is a triangular shape. A depth of recess 29 in the direction perpendicular to first main surface 1 is 100 nm or more. A length of recess 29 in a direction obtained by projecting a <11-20> direction onto first main surface 1 is 80 μm or less. An area density of recess 29 in first main surface 1 is 0.1/cm² or less. A polytype of silicon carbide of a bottom surface of recess 29 is different from a polytype of silicon carbide of silicon carbide epitaxial layer 40.

(2) In silicon carbide epitaxial substrate 100 according to (1), the depth of recess 29 in the direction perpendicular to first main surface 1 may be 140 nm or less.

(3) In silicon carbide epitaxial substrate 100 according to (1) or (2), the length of recess 29 in the direction obtained by projecting the <11-20> direction onto first main surface 1 may be 15 μm or more.

(4) In silicon carbide epitaxial substrate 100 according to any of (1) to (3), the polytype of the silicon carbide of the bottom surface of recess 29 may be 3C.

(5) In silicon carbide epitaxial substrate 100 according to any of (1) to (4), the polytype of the silicon carbide of silicon carbide epitaxial layer 40 may be 4H.

(6) In silicon carbide epitaxial substrate 100 according to any of (1) to (5), the area density of recess 29 in first main surface 1 may be 0.005/cm² or more.

(7) In silicon carbide epitaxial substrate 100 according to any one of (1) to (6), first main surface 1 may be a plane inclined with respect to a (000-1) plane.

(8) Silicon carbide epitaxial substrate 100 according to any one of (1) to (7) may further have a stacking fault 20 that forms the bottom surface of recess 29. Silicon carbide epitaxial substrate 100 may not have a downfall contiguous to stacking fault 20.

(9) In silicon carbide epitaxial substrate 100 according to any of (1) to (8), a thickness of silicon carbide epitaxial layer 40 in the direction perpendicular to first main surface 1 may be 7 μm or more and 15 μm or less.

(10) In silicon carbide epitaxial substrate 100 according to any of (1) to (9), a diameter of first main surface 1 may be 100 mm or more.

(11) A method of manufacturing a silicon carbide semiconductor device according to the present disclosure has the following steps. Silicon carbide epitaxial substrate 100 according to any one of (1) to (10) is prepared. Silicon carbide epitaxial substrate 100 is processed.

### DETAILS OF EMBODIMENTS OF THE PRESENT DISCLOSURE

Hereinafter, embodiments of the present disclosure will be described in detail with reference to figures. It should be noted that in the below-mentioned figures, the same or corresponding portions are given the same reference characters and are not described repeatedly.

### (Silicon Carbide Epitaxial Substrate)

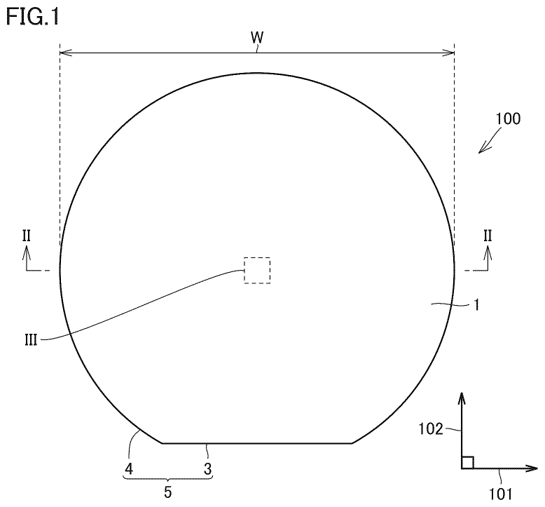

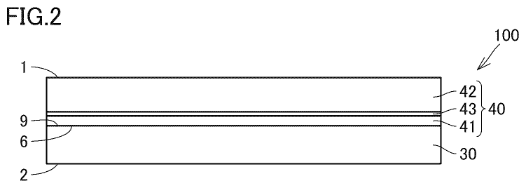

FIG. 1 is a schematic plan view showing a configuration of a silicon carbide epitaxial substrate 100 according to the present embodiment. FIG. 2 is a schematic cross sectional view along a line II-II of FIG. 1. As shown in FIGS. 1 and 2, silicon carbide epitaxial substrate 100 according to the present embodiment has a silicon carbide substrate 30 and a silicon carbide epitaxial layer 40. Silicon carbide epitaxial layer 40 is located on silicon carbide substrate 30. Silicon carbide epitaxial layer 40 is in contact with silicon carbide substrate 30. Silicon carbide epitaxial layer 40 has a first main surface 1.

Silicon carbide epitaxial layer 40 constitutes a front surface (first main surface 1) of silicon carbide epitaxial substrate 100. Silicon carbide substrate 30 constitutes a backside surface (second main surface 2) of silicon carbide epitaxial substrate 100. As shown in FIG. 1, silicon carbide epitaxial substrate 100 has an outer peripheral edge 5. Outer peripheral edge 5 has, for example, an orientation flat 3 and an arc-shaped portion 4. Orientation flat 3 extends along a first direction 101. As shown in FIG. 1, orientation flat 3 is in the form of a straight line as viewed in a direction perpendicular to first main surface 1. Arc-shaped portion 4 is contiguous to orientation flat 3. Arc-shaped portion 4 has an arc shape as viewed in the direction perpendicular to first main surface 1.

As shown in FIG. 1, as viewed in the direction perpendicular to first main surface 1, first main surface 1 is expanded along each of first direction 101 and a second direction 102. As viewed in the direction perpendicular to first main surface 1, second direction 102 is a direction perpendicular to first direction 101.

First direction 101 is a direction obtained by projecting a <11-20> direction onto first main surface 1. From another viewpoint, it can be said that first direction 101 is a direction including a <11-20> direction component.

Second direction 102 is, for example, a <1-100> direction. Second direction 102 may be, for example, a [1-100] direction. Second direction 102 may be, for example, a direction obtained by projecting the <1-100> direction onto first main surface 1. From another viewpoint, it can be said that second direction 102 may be a direction including a <1-100> direction component, for example.

First main surface 1 is a plane inclined with respect to a {0001} plane. An inclination angle (off angle θ) thereof with respect to the {0001} plane is, for example, more than 0° and 8° or less. Off angle θ is not particularly limited, but may be, for example, 1° or more or 2° or more. Off angle θ is not particularly limited, but may be, for example, 7° or less or 6° or less. First main surface 1 may be a plane inclined by off angle θ with respect to a (000-1) plane, or may be a plane inclined by off angle θ with respect to a (0001) plane. An inclination direction (off direction) of first main surface 1 is, for example, the <11-20> direction.

As shown in FIG. 1, a maximum diameter W (diameter) of first main surface 1 is not particularly limited, but is, for example, 100 mm (4 inches) or more. Maximum diameter W may be 125 mm (5 inches) or more, or 150 mm (6 inches) or more. Maximum diameter W may be, for example, 200 mm (8 inches) or less. Maximum diameter W is the maximum distance between any two points on outer peripheral edge 5.

It should be noted that in the present specification, 4 inches mean 100 mm or 101.6 mm (4 inches×25.4 mm/inch). 6 inches mean 150 mm or 152.4 mm (6 inches×25.4 mm/inch). 8 inches mean 200 mm or 203.2 mm (8 inches×25.4 mm/inch).

As shown in FIG. 2, silicon carbide substrate 30 has second main surface 2 and a third main surface 9. Third main surface 9 is located opposite to second main surface 2. Second main surface 2 is the backside surface of silicon carbide epitaxial substrate 100. Second main surface 2 is separated from silicon carbide epitaxial layer 40. Third main surface 9 is in contact with silicon carbide epitaxial layer 40. A polytype of silicon carbide of silicon carbide substrate 30 is, for example, 4H. Similarly, a polytype of silicon carbide of silicon carbide epitaxial layer 40 is, for example, 4H.

As shown in FIG. 2, silicon carbide epitaxial layer 40 has a fourth main surface 6. At fourth main surface 6, silicon carbide epitaxial layer 40 is in contact with silicon carbide substrate 30. Silicon carbide epitaxial layer 40 has a buffer layer 41, a transition layer 43, and a drift layer 42. Drift layer 42 may be a single layer or two or more layers.

Buffer layer 41 is located on silicon carbide substrate 30. Buffer layer 41 is in contact with silicon carbide substrate 30. Transition layer 43 is located on buffer layer 41. Transition layer 43 is in contact with buffer layer 41. Drift layer 42 is located on transition layer 43. Drift layer 42 is in contact with transition layer 43. Drift layer 42 constitutes first main surface 1. Buffer layer 41 constitutes fourth main surface 6.

Silicon carbide substrate 30 includes an n type impurity such as nitrogen (N), for example. The conductivity type of silicon carbide substrate 30 is n type, for example. The thickness of silicon carbide substrate 30 is 200 μm or more and 600 μm or less, for example. Silicon carbide epitaxial layer 40 includes an n type impurity such as nitrogen, for example. The conductivity type of silicon carbide epitaxial layer 40 is, for example, n type.

The concentration of the n type impurity included in buffer layer 41 may be lower than the concentration of the n type impurity included in silicon carbide substrate 30. The concentration of the n type impurity included in drift layer 42 may be lower than the concentration of the n type impurity included in buffer layer 41. The concentration of the n type impurity included in transition layer 43 may be lower than the concentration of the n type impurity included in buffer layer 41 and may be higher than the concentration of the n type impurity included in drift layer 42.

The concentration of the n type impurity included in transition layer 43 may be monotonously decreased in a direction from buffer layer 41 toward drift layer 42. The concentration of the n type impurity included in drift layer 42 is, for example, about 1×10¹⁴ cm⁻³ or more and 1×10¹⁷ cm⁻³ or less. The concentration of the n type impurity included in buffer layer 41 is, for example, about 1×10¹⁸ cm⁻³ or more and 1×10¹⁹ cm⁻³ or less.

### (Stacking Fault and Recess)

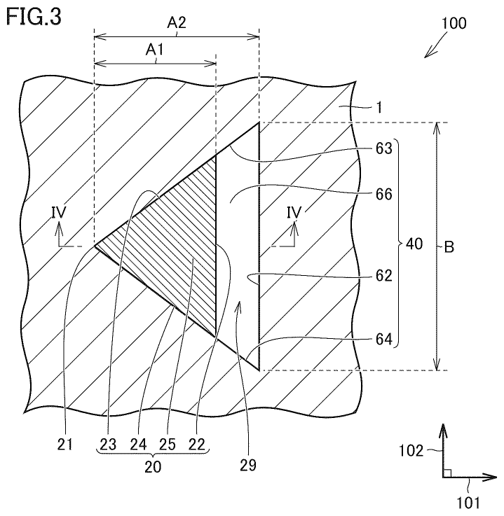

FIG. 3 is an enlarged schematic plan view of a region III in FIG. 1. The enlarged schematic plan view shown in FIG. 3 shows a state observed by a confocal differential interference microscope. As shown in FIG. 3, silicon carbide epitaxial substrate 100 according to the present embodiment has a stacking fault 20. As shown in FIG. 3, a shape of stacking fault 20 is, for example, a triangular shape as viewed in the direction perpendicular to first main surface 1.

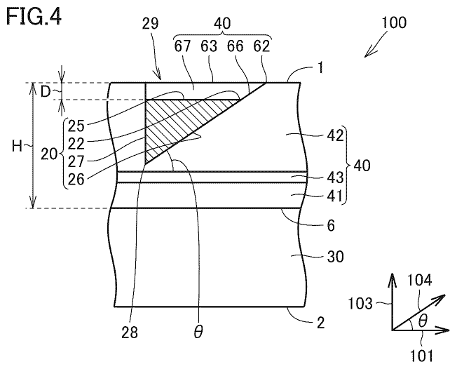

FIG. 4 is a schematic cross sectional view along a line IV-IV of FIG. 3. The cross section shown in FIG. 4 is a cross section perpendicular to first main surface 1. As shown in FIGS. 3 and 4, a recess 29 is formed in first main surface 1 of silicon carbide epitaxial substrate 100 according to the present embodiment. Recess 29 is constituted of silicon carbide epitaxial layer 40 and stacking fault 20. As viewed in the direction perpendicular to first main surface 1, an outer shape of recess 29 is a triangular shape.

As shown in FIG. 3, stacking fault 20 has a first side portion 23, a second side portion 24, a first bottom side portion 22, and a top surface portion 25. Second side portion 24 is contiguous to first side portion 23. A boundary between second side portion 24 and first side portion 23 is an apex 21. From another viewpoint, it can be said that the two side portions, i.e., first side portion 23 and second side portion 24 are branched from apex 21. First bottom side portion 22 is contiguous to each of first side portion 23 and second side portion 24. First side portion 23 is contiguous to one end (first end portion) of first bottom side portion 22, and second side portion 24 is contiguous to the other end (second end portion) of first bottom side portion 22. Top surface portion 25 is surrounded by first side portion 23, second side portion 24, and first bottom side portion 22. As viewed in the direction perpendicular to first main surface 1, the shape of top surface portion 25 is a triangular shape.

As viewed in the direction perpendicular to first main surface 1, first side portion 23 is inclined with respect to each of first direction 101 and second direction 102. First side portion 23 may be inclined to second direction 102 with respect to a straight line parallel to first direction 101. Second side portion 24 may be inclined, to a direction opposite to second direction 102, with respect to the straight line parallel to first direction 101. As viewed in the direction perpendicular to first main surface 1, first bottom side portion 22 extends along second direction 102. As viewed in the direction perpendicular to first main surface 1, the width of stacking fault 20 in second direction 102 may be increased in a direction from apex 21 toward first bottom side portion 22.

As shown in FIG. 3, silicon carbide epitaxial layer 40 has a third side portion 63, a fourth side portion 64, and a second bottom side portion 62. As viewed in the direction perpendicular to first main surface 1, a portion of third side portion 63 may overlap with first side portion 23 of stacking fault 20. As viewed in the direction perpendicular to first main surface 1, a portion of fourth side portion 64 may overlap with second side portion 24 of stacking fault 20.

As shown in FIG. 3, fourth side portion 64 is contiguous to third side portion 63 at apex 21 as viewed in the direction perpendicular to first main surface 1. From another viewpoint, it can be said that as viewed in the direction perpendicular to first main surface 1, two side portions, i.e., third side portion 63 and fourth side portion 64 are branch from apex 21. Second bottom side portion 62 is contiguous to each of third side portion 63 and fourth side portion 64. Third side portion 63 is contiguous to one end (third end portion) of second bottom side portion 62, and fourth side portion 64 is contiguous to the other end (fourth end portion) of second bottom side portion 62.

As viewed in the direction perpendicular to first main surface 1, third side portion 63 is inclined with respect to each of first direction 101 and second direction 102. Third side portion 63 may be inclined to second direction 102 with respect to a straight line parallel to first direction 101. Third side portion 63 may be substantially parallel to first side portion 23 of stacking fault 20. Fourth side portion 64 may be inclined, to a direction opposite to second direction 102, with respect to a straight line parallel to first direction 101. Fourth side portion 64 may be substantially parallel to second side portion 24 of stacking fault 20. As viewed in the direction perpendicular to first main surface 1, second bottom side portion 62 extends along second direction 102. Second bottom side portion 62 may be substantially parallel to first bottom side portion 22 of stacking fault 20 as viewed in the direction perpendicular to first main surface 1.

As shown in FIG. 3, the length of stacking fault 20 in first direction 101 is defined as a first length A1. First length A1 is a distance between apex 21 and first bottom side portion 22 as viewed in the direction perpendicular to first main surface 1. First length A1 is, for example, 10 μm or more and 60 μm or less.

As shown in FIG. 3, the length of recess 29 in first direction 101 is defined as a second length A2. Second length A2 is a distance between apex 21 and second bottom side portion 62 as viewed in the direction perpendicular to first main surface 1. Second length A2 is 80 μm or less. Second length A2 is not particularly limited, but may be, for example, 70 μm or less or 60 μm or less. Second length A2 is not particularly limited, but may be, for example, 15 μm or more, or 20 μm or more.

The width of recess 29 in the <1-100> direction (second direction 102) as viewed in the direction perpendicular to first main surface 1 is defined as a width B. Width B may be equal to the length of second bottom side portion 62. A ratio of width B to second length A2 is, for example, 0.5 or more and 5 or less. The ratio of width B to second length A2 is not particularly limited, but may be 0.8 or more, or may be 1.2 or more, for example. The ratio of width B to second length A2 is not particularly limited, but may be, for example, 4 or less or 3 or less. As viewed in the direction perpendicular to first main surface 1, the width of recess 29 in second direction 102 may be increased in the direction from apex 21 toward second bottom side portion 62.

As shown in FIG. 4, stacking fault 20 may have a first side surface portion 27 and a bottom surface portion 26. First side surface portion 27 extends along a third direction 103. Bottom surface portion 26 extends along a fourth direction 104. A plane extending along fourth direction 104 is a basal plane. Bottom surface portion 26 is contiguous to first side surface portion 27. A boundary between bottom surface portion 26 and first side surface portion 27 is defined as a starting point 28.

Third direction 103 is a direction perpendicular to each of first direction 101 and second direction 102. Fourth direction 104 is inclined with respect to each of first direction 101 and third direction 103. Fourth direction 104 is inclined to third direction 103 with respect to first direction 101. An angle formed by fourth direction 104 and first direction 101 is off angle θ.

Top surface portion 25 is contiguous to each of bottom surface portion 26 and first side surface portion 27. Top surface portion 25 extends along first direction 101. Top surface portion 25 may be substantially parallel to first main surface 1. Top surface portion 25 forms a bottom surface of recess 29. The plane orientation of top surface portion 25 may be the same as the plane orientation of first main surface 1.

Starting point 28 is located in, for example, drift layer 42. From another viewpoint, it can be said that starting point 28 is located between first main surface 1 and transition layer 43 in third direction 103, for example. Silicon carbide epitaxial substrate 100 according to the present embodiment does not have a downfall contiguous to stacking fault 20. The downfall is, for example, a substance or the like having fallen onto silicon carbide substrate 30 from an inner wall of a film forming apparatus on which the substance or the like has been adhered. The downfall is, for example, a polycrystalline silicon carbide particle. The downfall may be, for example, a carbide particle.

A silicon droplet may be present at starting point 28. From another viewpoint, it can be said that silicon carbide epitaxial substrate 100 may have the silicon droplet. A silicon particle formed by solidification of the silicon droplet may be present at starting point 28. From another viewpoint, it can be said that silicon carbide epitaxial substrate 100 may have the silicon particle. At starting point 28, stacking fault 20 may be contiguous to the silicon particle.

The length of stacking fault 20 in first direction 101 may be increased in a direction from starting point 28 toward top surface portion 25. It should be noted that starting point 28 may be located in transition layer 43 or buffer layer 41. In other words, bottom surface portion 26 may extend through each of transition layer 43 and drift layer 42.

As shown in FIG. 4, silicon carbide epitaxial layer 40 has a second side surface portion 67 and a third side surface portion 66. Second side surface portion 67 may extend along third direction 103. Second side surface portion 67 may extend along first side surface portion 27 of stacking fault 20.

Third side surface portion 66 is contiguous to second side surface portion 67. Third side surface portion 66 extends along fourth direction 104. Third side surface portion 66 may extend along bottom surface portion 26 of stacking fault 20. Second side surface portion 67 and third side surface portion 66 form the side surface of recess 29.

As shown in FIGS. 3 and 4, recess 29 is defined by top surface portion 25 of stacking fault 20 and second side surface portion 67 and third side surface portion 66 of silicon carbide epitaxial layer 40. From another viewpoint, it can be said that the bottom surface of recess 29 is formed by stacking fault 20. The side surface of recess 29 is formed by silicon carbide epitaxial layer 40.

The polytype of silicon carbide of stacking fault 20 is different from the polytype of silicon carbide of silicon carbide epitaxial layer 40. From another viewpoint, it can be said that the polytype of the silicon carbide of the bottom surface of recess 29 is different from the polytype of the silicon carbide of silicon carbide epitaxial layer 40. The polytype of the silicon carbide of stacking fault 20 is, for example, 3C. From another viewpoint, it can be said that the polytype of silicon carbide of the bottom surface of recess 29 is, for example, 3C.

As shown in FIG. 4, the thickness of silicon carbide epitaxial layer 40 in the direction perpendicular to first main surface 1 is defined as a thickness H. Thickness H is, for example, 7 μm or more and 15 μm or less. Thickness H is not particularly limited, but may be, for example, 8 μm or more, or 9 μm or more. Thickness H is not particularly limited, but may be, for example, 14 μm or less or 13 μm or less.

As shown in FIG. 4, the depth of recess 29 in the direction perpendicular to first main surface 1 is defined as a depth D. Depth D is a distance between first main surface 1 and top surface portion 25 in the direction perpendicular to first main surface 1. Depth D is 100 nm or more. Depth D is not particularly limited, but may be, for example, 105 nm or more, or 110 nm or more. Depth D is not particularly limited, but may be, for example, 140 nm or less, 135 nm or less, or 130 nm or less.

Depth D can be measured using a white light interferometric microscope (product name: “BW-D507”) provided by Nikon, for example. A mercury lamp is used as a light source. A measurement visual field is 256 μm×256 μm. Light emitted from the light source is split into two beams of light by a beam splitter. One of the beams of light is emitted to a reference surface. The other of the beams of light is emitted to first surface 1 and top surface portion 25. Light reflected from the both forms an image in a camera. Depth D is measured based on information of interference fringe as obtained from an optical path difference caused by irregularities formed in first main surface 1 and top surface portion 25.

### (Area Density of Recess)

Next, a method of measuring an area density of recess 29 in first main surface 1 will be described. Recess 29 is specified by observing first main surface 1 of silicon carbide epitaxial substrate 100 using a defect inspection apparatus having a confocal differential interference microscope. As the defect inspection apparatus having a confocal differential interference microscope, for example, WASAVI series “SICA 6X” provided by Lasertec can be used. The magnification of its objective lens is, for example, 10 times. Light having a wavelength of 546 nm is applied from a light source such as a mercury xenon lamp to first main surface 1 of silicon carbide epitaxial substrate 100, and reflected light thereof is observed by a light receiving element. A threshold value, which is an index of measurement sensitivity of the SICA, is Thresh S40, for example.

In a measurement region of first main surface 1, the number of recesses 29 is found. Specifically, first, a confocal differential interference image (SICA image) in the entire measurement region of first main surface 1 of silicon carbide epitaxial substrate 100 is measured using “SICA 6X”. The total number of recesses 29 in the measurement region of first main surface 1 is counted based on the SICA image. The area density of recess 29 in first main surface 1 is a value obtained by dividing the total number of recesses 29 in the measurement region of first main surface 1 by the area of the measurement region of first main surface 1. It should be noted that in first main surface 1, a region within 5 mm from outer peripheral edge 5 is excluded from the measurement region for the area density of recess 29 (edge exclusion).

The area density of recess 29 in first main surface 1 is 0.1/cm² or less. The area density of recess 29 in first main surface 1 is not particularly limited, but may be, for example, 0.08/cm² or less, or 0.06/cm² or less. The area density of recesses 29 in first main surface 1 is not particularly limited, but may be, for example, 0.005/cm² or more, 0.01/cm² or more, or 0.02/cm² or more.

### (Manufacturing Apparatus for Silicon Carbide Epitaxial Substrate)

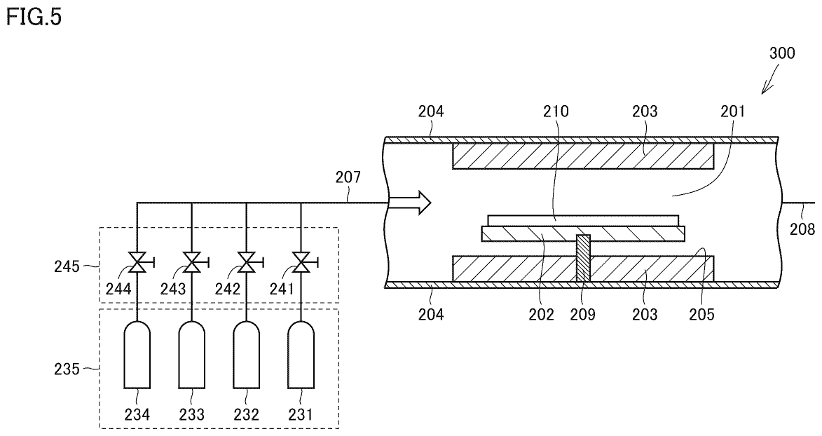

Next, a configuration of a manufacturing apparatus for silicon carbide epitaxial substrate 100 will be described. FIG. 5 is a partial schematic cross sectional view showing the configuration of the manufacturing apparatus for silicon carbide epitaxial substrate 100. A manufacturing apparatus 300 for silicon carbide epitaxial substrate 100 is, for example, a hot wall type lateral CVD (Chemical Vapor Deposition) apparatus. As shown in FIG. 5, manufacturing apparatus 300 for silicon carbide epitaxial substrate 100 mainly has a reaction chamber 201, a gas supply unit 235, a control unit 245, a heating element 203, a quartz tube 204, a heat insulating material (not shown), and an induction heating coil (not shown).

Heating element 203 has, for example, a tubular shape, and forms reaction chamber 201 therein. Heating element 203 is composed of graphite, for example. Heating element 203 is provided inside quartz tube 204. The heat insulating material surrounds the outer periphery of heating element 203. The induction heating coil is wound, for example, along the outer peripheral surface of quartz tube 204. The induction heating coil can be supplied with an alternating current by an external power supply (not shown). Thus, heating element 203 is inductively heated. As a result, reaction chamber 201 is heated by heating element 203.

Reaction chamber 201 is a formed space surrounded by an inner wall surface 205 of heating element 203. A susceptor 210 that holds silicon carbide substrate 30 is provided in reaction chamber 201. Susceptor 210 is composed of silicon carbide. Silicon carbide substrate 30 is placed on susceptor 210. Susceptor 210 is disposed on a stage 202. Stage 202 is rotatably supported by a rotation shaft 209. When stage 202 is rotated, susceptor 210 is rotated.

Manufacturing apparatus 300 for silicon carbide epitaxial substrate 100 further has a gas introduction port 207 and a gas discharging port 208. Gas discharging port 208 is connected to a gas discharging pump (not shown). An arrow in FIG. 5 indicates a flow of gas. The gas is introduced from gas introduction port 207 into reaction chamber 201 and is discharged from gas discharging port 208. Pressure in reaction chamber 201 is adjusted in accordance with a balance between an amount of supply of the gas and an amount of discharging of the gas.

Gas supply unit 235 is configured to supply reaction chamber 201 with a mixed gas including a source gas, a dopant gas, and a carrier gas. Specifically, gas supply unit 235 includes, for example, a first gas supply unit 231, a second gas supply unit 232, a third gas supply unit 233, and a fourth gas supply unit 234.

First gas supply unit 231 is configured to supply a first gas including carbon atoms, for example. First gas supply unit 231 is, for example, a gas cylinder provided with the first gas. The first gas is, for example, propane (C₃H₈) gas. The first gas may be, for example, methane (CH₄) gas, ethane (C₂H₆) gas, acetylene (C₂H₂) gas, or the like.

Second gas supply unit 232 is configured to supply a second gas including, for example, a silane gas. Second gas supply unit 232 is, for example, a gas cylinder provided with the second gas. The second gas is, for example, silane (SiH₄) gas. The second gas may be a mixed gas of the silane gas and a gas other than silane.

Third gas supply unit 233 is configured to supply a third gas including, for example, nitrogen atoms. Third gas supply unit 233 is, for example, a gas cylinder provided with the third gas. The third gas is a doping gas. The third gas is, for example, ammonia gas. The ammonia gas is more likely to be thermally decomposed than nitrogen gas having a triple bond.

Fourth gas supply unit 234 is configured to supply a fourth gas (carrier gas) such as hydrogen, for example. Fourth gas supply unit 234 is, for example, a gas cylinder provided with hydrogen. The fourth gas may be argon gas.

Control unit 245 is configured to control a flow rate of the mixed gas to be supplied from gas supply unit 235 to reaction chamber 201. Specifically, control unit 245 may include a first gas flow rate control unit 241, a second gas flow rate control unit 242, a third gas flow rate control unit 243, and a fourth gas flow rate control unit 244. Each control unit may be, for example, an MFC (mass flow controller). Control unit 245 is disposed between gas supply unit 235 and gas introduction port 207.

### (Method of Manufacturing Silicon Carbide Epitaxial Substrate)

Next, a method of manufacturing silicon carbide epitaxial substrate 100 according to the present embodiment will be described.

First, silicon carbide substrate 30 is prepared. For example, a silicon carbide single crystal having a polytype of 4H is produced by a sublimation method. Next, the silicon carbide single crystal is sliced by, for example, a wire saw to prepare silicon carbide substrate 30. Silicon carbide substrate 30 includes, for example, an n type impurity such as nitrogen. The conductivity type of silicon carbide substrate 30 is n type, for example. Next, mechanical polishing is performed onto silicon carbide substrate 30. Next, chemical mechanical polishing is performed onto silicon carbide substrate 30.

Next, silicon carbide epitaxial layer 40 is formed on silicon carbide substrate 30. Specifically, silicon carbide epitaxial layer 40 is formed by epitaxial growth on third main surface 9 of silicon carbide substrate 30 using the hot wall type lateral CVD apparatus shown in FIG. 5. In the epitaxial growth, for example, silane (SiH₄) and propane (C₃H₈) are each used as the source gas, and hydrogen (H₂) is used as the carrier gas. In the epitaxial growth, an n type impurity such as nitrogen is introduced into silicon carbide epitaxial layer 40.

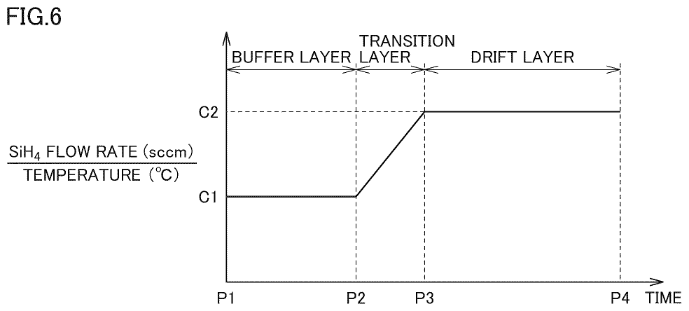

FIG. 6 is a schematic diagram showing a relation between a time and a silane flow rate with respect to a temperature. The silane flow rate with respect to the temperature is a value obtained by dividing the silane flow rate (sccm) by the temperature (° C.). As shown in FIG. 6, at a first time point P1, the silane flow rate with respect to the temperature is set to a first ratio C1. During a period from first time point P1 to a second time point P2, the silane flow rate with respect to the temperature is maintained at first ratio C1. During the period from first time point P1 to second time point P2, buffer layer 41 is formed on silicon carbide substrate 30.

During a period from second time point P2 to a third time point P3, the silane flow rate with respect to the temperature is monotonously increased. During the period from second time point P2 to third time point P3, the silane flow rate with respect to the temperature is increased from first ratio C1 to a second ratio C2. During the period from second time point P2 to third time point P3, transition layer 43 is formed on buffer layer 41. During a period from third time point P3 to a fourth time point P4, the silane flow rate with respect to the temperature is maintained at second ratio C2. During the period from third time point P3 to fourth time point P4, drift layer 42 is formed on transition layer 43.

The silane flow rate with respect to the temperature is adjusted while changing each of the silane flow rate and the temperature. First ratio C1 is, for example, 0.036 (sccm/° C.). Second ratio C2 is, for example, 0.044 (sccm/° C.). During the period from second time point P2 to third time point P3, the silane flow rate with respect to the temperature may be increased at a ratio of 0.002 (sccm/° C.) per minute, for example.

A temperature at which drift layer 42 is formed is higher than a temperature at which buffer layer 41 is formed, for example. The temperature at which drift layer 42 is formed is, for example, 1720° C. The temperature at which buffer layer 41 is formed is, for example, 1610° C. In the step of forming transition layer 43, the temperature is increased, for example. In this way, silicon carbide epitaxial substrate 100 having silicon carbide substrate 30 and silicon carbide epitaxial layer 40 is produced (see FIG. 2).

When forming silicon carbide epitaxial layer 40, the silane gas and the propane gas are used. When compared at the same temperature, the silane gas has such a property that the silane gas is likely to be decomposed than the propane gas. As a result of diligent study, the inventors have found that recess 29 can be effectively reduced by controlling the ratio of the silane gas flow rate with respect to the temperature.

It is considered that each of stacking fault 20 and recess 29 is formed due to a silicon droplet. Specifically, it is considered that stacking fault 20 is formed due to the silicon droplet and stacking fault 20 forms recess 29. With the method of manufacturing silicon carbide epitaxial substrate 100 according to the present embodiment, the silicon droplet can be suppressed from being formed from decomposed silane gas, with the result that it is considered that stacking fault 20 can be suppressed from being formed due to the silicon droplet. Thus, it is considered that the area density of recess 29 in first main surface 1 can be reduced.

### (Method of Manufacturing Silicon Carbide Semiconductor Device)

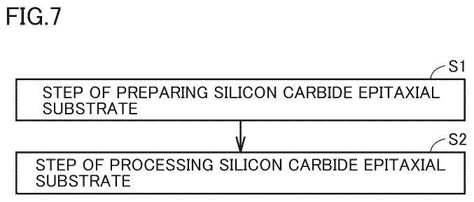

Next, a method of manufacturing a silicon carbide semiconductor device 400 according to the present embodiment will be described. FIG. 7 is a flowchart schematically showing the method of manufacturing a silicon carbide semiconductor device according to the present embodiment. As shown in FIG. 7, the method of manufacturing silicon carbide semiconductor device 400 according to the present embodiment mainly has a step (S1) of preparing the silicon carbide epitaxial substrate and a step (S2) of processing the silicon carbide epitaxial substrate.

First, the step (S1) of preparing the silicon carbide epitaxial substrate is performed. In the step (S1) of preparing the silicon carbide epitaxial substrate, silicon carbide epitaxial substrate 100 according to the present embodiment is prepared (see FIG. 1).

Next, the step (S2) of processing the silicon carbide epitaxial substrate is performed. Specifically, the following processes are performed to silicon carbide epitaxial substrate 100. First, ion implantation is performed into silicon carbide epitaxial substrate 100.

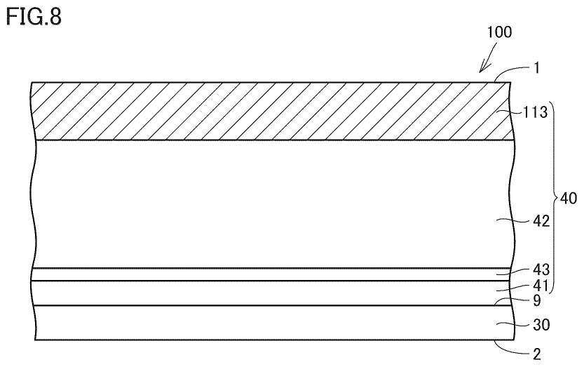

FIG. 8 is a schematic cross sectional view showing a step of forming a body region. In the step of forming the body region, ion implantation of a p type impurity such as aluminum is performed into first main surface 1 of silicon carbide epitaxial layer 40, for example. Thus, a body region 113 having p type conductivity is formed. A portion in which no body region 113 is formed serves as drift layer 42. The thickness of body region 113 is, for example, 0.9 μm.

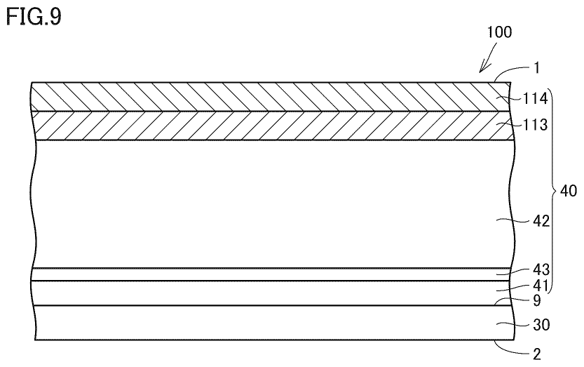

Next, a step of forming a source region is performed. FIG. 9 is a schematic cross sectional view showing the step of forming the source region. Specifically, ion implantation of an n type impurity such as phosphorus is performed into body region 113. Thus, a source region 114 having n type conductivity is formed. The thickness of source region 114 is, for example, 0.4 μm. The concentration of the n type impurity included in source region 114 is higher than the concentration of the p type impurity included in body region 113.

Next, ion implantation of a p type impurity such as aluminum is performed into source region 114 so as to form a contact region 118. Contact region 118 is formed to extend through source region 114 and body region 113 and come into contact with drift layer 42. The concentration of the p type impurity included in contact region 118 is higher than the concentration of the n type impurity included in source region 114.

Next, activation annealing is performed to activate the impurities implanted by the ion implantation. A temperature of the activation annealing is, for example, 1500° C. or more and 1900° C. or less. A time of the activation annealing is, for example, about 30 minutes. An atmosphere of the activation annealing is, for example, an argon atmosphere.

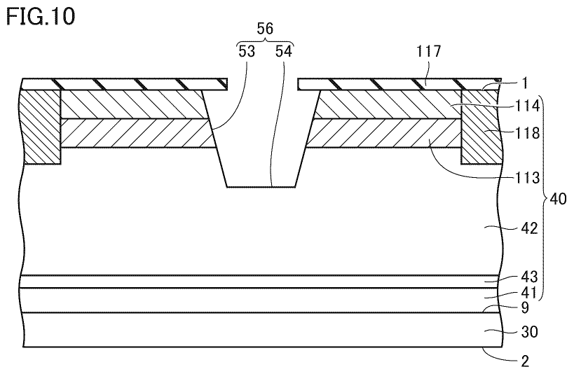

Next, a step of forming a trench in first main surface 1 of silicon carbide epitaxial layer 40 is performed. FIG. 10 is a schematic cross sectional view showing the step of forming the trench in first main surface 1 of silicon carbide epitaxial layer 40. A mask 117 provided with an opening is formed on first main surface 1 constituted of source region 114 and contact region 118. Source region 114, body region 113, and a portion of drift layer 42 are removed by etching using mask 117. As the etching method, for example, inductively coupled plasma reactive ion etching can be used. Specifically, for example, inductively coupled plasma reactive ion etching using SF₆ or a mixed gas of SF₆ and O₂ as a reaction gas is used. A depression is formed in first main surface 1 by the etching.

Next, thermal etching is performed in the depression. The thermal etching may be performed, for example, by heating in an atmosphere including a reactive gas having at least one type of halogen atom with mask 117 being formed on first main surface 1. The at least one type of halogen atom includes at least one of a chlorine (Cl) atom and a fluorine (F) atom. The atmosphere includes, for example, Cl₂, BCl₃, SF₆, or CF₄. For example, the thermal etching is performed using a mixed gas of chlorine gas and oxygen gas as a reactive gas at a heat treatment temperature of, for example, 700° C. or more and 1000° C. or less. It should be noted that the reactive gas may include a carrier gas in addition to the chlorine gas and the oxygen gas. An exemplary, usable carrier gas is nitrogen gas, argon gas, helium gas, or the like.

As shown in FIG. 10, a trench 56 is formed in first main surface 1 by thermal etching. Trench 56 is defined by a side wall surface 53 and a bottom wall surface 54. Side wall surface 53 is constituted of source region 114, body region 113, and drift layer 42. Bottom wall surface 54 is constituted of drift layer 42. Next, mask 117 is removed from first main surface 1.

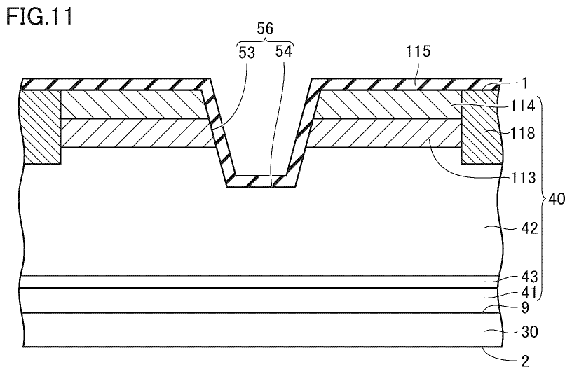

Next, a step of forming a gate insulating film is performed. FIG. 11 is a schematic cross sectional view showing the step of forming the gate insulating film. Specifically, silicon carbide epitaxial substrate 100 in which trench 56 is formed in first main surface 1 is heated in an atmosphere including oxygen at a temperature of, for example, 1300° C. or more and 1400° C. or less. Thus, a gate insulating film 115 is formed in contact with drift layer 42 at bottom wall surface 54, in contact with each of drift layer 42, body region 113, and source region 114 at side wall surface 53, and in contact with each of source region 114 and contact region 118 at first main surface 1.

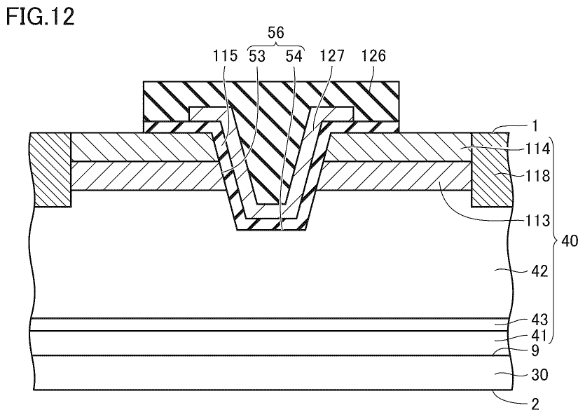

Next, a step of forming a gate electrode is performed. FIG. 12 is a schematic cross sectional view showing the step of forming the gate electrode and an interlayer insulating film. A gate electrode 127 is formed inside trench 56 so as to be in contact with gate insulating film 115. Gate electrode 127 is disposed inside trench 56, and is formed on gate insulating film 115 so as to face each of side wall surface 53 and bottom wall surface 54 of trench 56. Gate electrode 127 is formed by, for example, an LPCVD (Low Pressure Chemical Vapor Deposition) method.

Next, an interlayer insulating film 126 is formed. Interlayer insulating film 126 is formed to cover gate electrode 127 and be in contact with gate insulating film 115. Interlayer insulating film 126 is formed by, for example, a chemical vapor deposition method. Interlayer insulating film 126 is composed of, for example, a material including silicon dioxide. Next, portions of interlayer insulating film 126 and gate insulating film 115 are etched to form an opening above source region 114 and contact region 118. Thus, contact region 118 and source region 114 are exposed from gate insulating film 115.

Next, a step of forming a source electrode is performed. A source electrode 116 is formed in contact with each of source region 114 and contact region 118. Source electrode 116 is formed by, for example, a sputtering method. Source electrode 116 is composed of, for example, a material including Ti (titanium), Al (aluminum), and Si (silicon).

Next, alloying annealing is performed. Specifically, source electrode 116 in contact with each of source region 114 and contact region 118 is held at a temperature of, for example, 900° C. or more and 1100° C. or less for about 5 minutes. Thus, at least a portion of source electrode 116 is silicided. In this way, source electrode 116 in ohmic contact with source region 114 is formed. Source electrode 116 may be in ohmic contact with contact region 118.

Next, a source wiring 119 is formed. Source wiring 119 is electrically connected to source electrode 116. Source wiring 119 is formed to cover source electrode 116 and interlayer insulating film 126.

Next, a step of forming a drain electrode is performed. First, second main surface 2 of silicon carbide substrate 30 is polished. Thus, the thickness of silicon carbide substrate 30 is reduced. Next, a drain electrode 123 is formed. Drain electrode 123 is formed in contact with second main surface 2. In this way, silicon carbide semiconductor device 400 according to the present embodiment is manufactured.

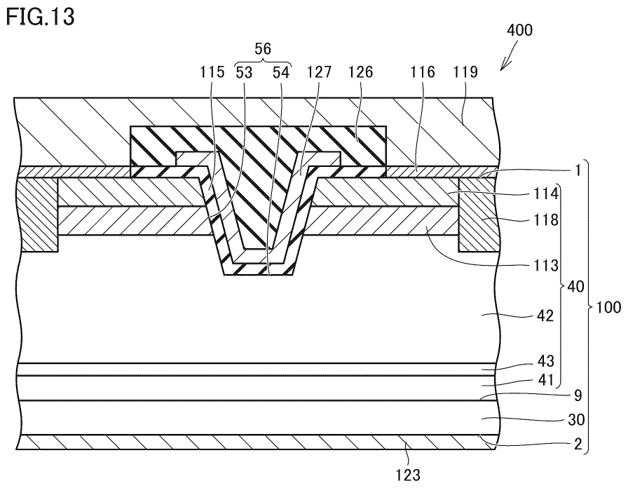

FIG. 13 is a schematic cross sectional view showing a configuration of the silicon carbide semiconductor device according to the present embodiment. Silicon carbide semiconductor device 400 is, for example, a MOSFET (Metal Oxide Semiconductor Field Effect Transistor). Silicon carbide semiconductor device 400 mainly has silicon carbide epitaxial substrate 100, gate electrode 127, gate insulating film 115, source electrode 116, drain electrode 123, source wiring 119, and interlayer insulating film 126. Silicon carbide epitaxial substrate 100 has drift layer 42, body region 113, source region 114, and contact region 118. Silicon carbide semiconductor device 400 may be, for example, an IGBT (Insulated Gate Bipolar Transistor) or the like.

Next, functions and effects of silicon carbide epitaxial substrate 100 and the method of manufacturing a silicon carbide semiconductor device according to the present embodiment will be described.

In general, in the process of producing silicon carbide epitaxial substrate 100, as the flow rate of silane is higher, the growth rate of silicon carbide epitaxial layer 40 is higher. However, when the flow rate of silane is excessively increased, yield of the silicon carbide semiconductor device may be decreased.

The inventors have obtained the following finding during detailed investigation for the cause of the decreased yield of the silicon carbide semiconductor device. Specifically, the inventors have found that when silicon carbide semiconductor device 400 is manufactured using silicon carbide epitaxial substrate 100 in which recess 29 having a certain specific shape is formed, silicon carbide semiconductor device 400 is likely to have an insufficient characteristic.

It is considered that recess 29 having such a specific shape is formed due to the silicon droplet in the process of forming silicon carbide epitaxial layer 40. Stacking fault 20 formed due to a downfall such as a carbon particle or silicon carbide particle may protrude to third direction 103 with respect to first main surface 1. On the other hand, it is considered that stacking fault 20 formed by a silicon droplet does not protrude with respect to first main surface 1 and forms recess 29.

Therefore, the inventors have paid attention to the silane flow rate with respect to the temperature in the method of manufacturing silicon carbide epitaxial substrate 100. When the silane flow rate with respect to the temperature is too high, the silane is decomposed excessively to form the silicon droplet. This is considered to result in increase of recesses 29 in first main surface 1. Conversely, when the silane flow rate with respect to the temperature is excessively small, the growth rate of silicon carbide epitaxial layer 40 becomes excessively slow. With the method of manufacturing silicon carbide epitaxial substrate 100 according to the present embodiment, it is considered that the area density of recess 29 in first main surface 1 can be reduced while maintaining a high growth rate of silicon carbide epitaxial layer 40.

With silicon carbide epitaxial substrate 100 according to the present disclosure, the area density of recess 29 in first main surface 1 is 0.1/cm² or less. Therefore, the yield of silicon carbide semiconductor device 400 produced using silicon carbide epitaxial substrate 100 can be improved.

With silicon carbide epitaxial substrate 100 according to the present disclosure, the diameter (maximum diameter W) of first main surface 1 is 100 mm or more. Even when silicon carbide epitaxial substrate 100 having such a large diameter is used, the yield of silicon carbide semiconductor device 400 can be improved.

### Examples

### (Preparation of Samples)

First, silicon carbide epitaxial substrates 100 according to samples 1 to 6 were prepared. Silicon carbide epitaxial substrates 100 according to samples 1 to 3 are comparative examples. Silicon carbide epitaxial substrates 100 according to samples 4 to 6 are examples of the present disclosure. The diameter of each of silicon carbide epitaxial substrates 100 according to samples 1 to 6 was 150 mm.

Each of silicon carbide epitaxial substrates 100 according to samples 1 to 6 was manufactured in accordance with the method described in FIG. 6. Specifically, silicon carbide epitaxial substrate 100 was manufactured using conditions shown in Table 1.

TABLE 1

| | | Buffer Layer | Transition Layer | Drift Layer |
|---|---|---|---|---|
| Samples 1 to 3 | Temperature (° C.) | 1610 | 1610→1720 | 1720 |
| | H₂ Flow Rate (slm) | 134 | 134 | 134 |
| | SiH₄ Flow Rate | 57.5 | 57.5→96 | 96 |
| | (sccm) | | | |
| | C₃H₈ Flow Rate | 18 | 18→54.5 | 54.5 |
| | (sccm) | | | |
| | Time (Min.) | 20 | 4 | 90 |
| | SiH₄ Flow Rate/ | 0.036 | 0.005 (/Min.) | 0.056 |
| | Temperature | | | |
| | (sccm/° C.) | | | |
| Samples 4 to 6 | Temperature (° C.) | 1610 | 1610→1720 | 1720 |
| | H₂ Flow Rate (slm) | 134 | 134 | 134 |
| | SiH₄ Flow Rate | 57.5 | 57.5→75 | 75 |
| | (sccm) | | | |
| | C₃H₈ Flow Rate | 18 | 18→37.5 | 37.5 |
| | (sccm) | | | |
| | Time (Min.) | 20 | 4 | 90 |
| | SiH₄ Flow Rate/ | 0.036 | 0.002 (/Min.) | 0.044 |
| | Temperature | | | |
| | (sccm/° C.) | | | |

Each of silicon carbide epitaxial substrates 100 according to samples 1 to 3 was manufactured as follows.

During the period from first time point P1 to second time point P2, a temperature of reaction chamber 201 was set to 1610° C. During the period from second time point P2 to third time point P3, the temperature was increased from 1610° C. to 1720° C. During the period from third time point P3 to fourth time point P4, the temperature was set to 1720° C. During the period from first time point P1 to fourth time point P4, a H₂ flow rate was set to 134 slm.

During the period from first time point P1 to second time point P2, the SiH₄ flow rate was set to 57.5 sccm. During the period from second time point P2 to third time point P3, the SiH₄ flow rate was increased from 57.5 sccm to 96 sccm. During the period from third time point P3 to fourth time point P4, the SiH₄ flow rate was set to 96 sccm.

During the period from first time point P1 to second time point P2, the C₃H₈ flow rate was set to 18 sccm. During the period from second time point P2 to third time point P3, the C₃H₈ flow rate was increased from 18 sccm to 54.5 sccm. During the period from third time point P3 to fourth time point P4, the C₃H₈ flow rate was set to 54.5 sccm.

The period from first time point P1 to second time point P2 was 20 minutes. The period from second time point P2 to third time point P3 was 4 minutes. The period from third time point P3 to fourth time point P4 was 90 minutes.

During the period from first time point P1 to second time point P2, the SiH₄ flow rate/the temperature (sccm/° C.) was 0.036. During the period from second time point P2 to third time point P3, the SiH₄ flow rate/the temperature (sccm/° C.) was increased at a ratio of 0.005 per minute. During the period from third time point P3 to fourth time point P4, the SiH₄ flow rate/the temperature (sccm/° C.) was 0.056.

Each of silicon carbide epitaxial substrates 100 according to samples 4 to 6 was manufactured as follows.

During the period from first time point P1 to second time point P2, the temperature was set to 1610° C. During the period from second time point P2 to third time point P3, the temperature was increased from 1610° C. to 1720° C. During the period from third time point P3 to fourth time point P4, the temperature was set to 1610° C. During the period from first time point P1 to fourth time point P4, the H₂ flow rate was set to 134 slm.

During the period from first time point P1 to second time point P2, the SiH₄ flow rate was set to 57.5 sccm. During the period from second time point P2 to third time point P3, the SiH₄ flow rate was increased from 57.5 sccm to 75 sccm. During the period from third time point P3 to fourth time point P4, the SiH₄ flow rate was set to 75 sccm.

During the period from first time point P1 to second time point P2, the C₃H₈ flow rate was set to 18 sccm. During the period from second time point P2 to third time point P3, the C₃H₈ flow rate was increased from 18 sccm to 37.5 sccm. During the period from third time point P3 to fourth time point P4, the C₃H₈ flow rate was set to 37.5 sccm.

The period from first time point P1 to second time point P2 was 20 minutes. The period from second time point P2 to third time point P3 was 4 minutes. The period from third time point P3 to fourth time point P4 was 90 minutes.

During the period from first time point P1 to second time point P2, the SiH₄ flow rate/the temperature (sccm/° C.) was 0.036. During the period from second time point P2 to third time point P3, the SiH₄ flow rate/the temperature (sccm/° C.) was increased at a ratio of 0.002 per minute. During the period from third time point P3 to fourth time point P4, the SiH₄ flow rate/the temperature (sccm/° C.) was 0.044.

### (Experiment Method)

First main surface 1 of silicon carbide epitaxial substrate 100 according to each of samples 1 to 6 was imaged using WASAVI series “SICA 6X”, which is a confocal differential interference microscope provided by Lasertec. The area density of recess 29 was found by dividing the number of recesses 29 in the measurement region of first main surface 1 by the area of the measurement region of first main surface 1. The magnification of the objective lens was set to 10 times. Light having a wavelength of 546 nm was applied from a light source such as a mercury xenon lamp to first main surface 1 of silicon carbide epitaxial substrate 100, and reflected light thereof was observed by a light receiving element. A threshold value, which is an index of measurement sensitivity of the SICA, was Thresh S40, for example. In first main surface 1, a region within 5 mm from outer peripheral edge 5 was excluded from the measurement region for the area density of recess 29.

### (Experiment Result)

TABLE 2

| | Area Density of Recess |
|---|---|
| | (/cm²) |
| Sample 1 | 0.23 |
| Sample 2 | 0.14 |
| Sample 3 | 0.13 |
| Sample 4 | 0.08 |
| Sample 5 | 0.06 |
| Sample 6 | 0.04 |

Table 2 shows the area density of recess 29 in silicon carbide epitaxial substrate 100. As shown in Table 2, the area density of recess 29 in silicon carbide epitaxial substrates 100 according to each of samples 4 to 6 is smaller than the area density of recess 29 in silicon carbide epitaxial substrate 100 according to each of samples 1 to 3. In silicon carbide epitaxial substrate 100 according to each of samples 4 to 6, the area density of recess 29 was 0.1/cm² or less.

In view of the above results, it could be confirmed that the area density of recess 29 was reduced in silicon carbide epitaxial substrate 100 of each of the examples of the present disclosure as compared with silicon carbide epitaxial substrate 100 of each of the comparative examples.

The present disclosure includes the following embodiments.

### (Supplementary Note 1)

A silicon carbide epitaxial substrate comprising:
a silicon carbide substrate; and
a silicon carbide epitaxial layer located on the silicon carbide substrate and having a main surface, wherein
a recess is formed in the main surface,
as viewed in a direction perpendicular to the main surface, an outer shape of the recess is a triangular shape,
a depth of the recess in the direction perpendicular to the main surface is 100 nm or more,
a length of the recess in a direction obtained by projecting a <11-20> direction onto a first main surface is 80 μm or less,
an area density of the recess in the main surface is 0.1/cm² or less, and
a polytype of silicon carbide of a bottom surface of the recess is different from a polytype of silicon carbide of the silicon carbide epitaxial layer.

### (Supplementary Note 2)

The silicon carbide epitaxial substrate according to supplementary note 1, wherein the depth of the recess in the direction perpendicular to the main surface is 140 nm or less.

### (Supplementary Note 3)

The silicon carbide epitaxial substrate according to supplementary note 1 or 2, wherein the length of the recess in the direction obtained by projecting the <11-20> direction onto the first main surface is 15 μm or more.

### (Supplementary Note 4)

The silicon carbide epitaxial substrate according to supplementary note 1 or 2, wherein the polytype of the silicon carbide of the bottom surface of the recess is 3C.

### (Supplementary Note 5)

The silicon carbide epitaxial substrate according to supplementary note 1 or 2, wherein the polytype of the silicon carbide of the silicon carbide epitaxial layer is 4H.

### (Supplementary Note 6)

The silicon carbide epitaxial substrate according to supplementary note 1 or 2, wherein the area density of the recess in the main surface is 0.005/cm² or more.

### (Supplementary Note 7)

The silicon carbide epitaxial substrate according to supplementary note 1 or 2, wherein the main surface is a plane inclined with respect to a (000-1) plane.

### (Supplementary Note 8)

The silicon carbide epitaxial substrate according to supplementary note 1 or 2, further comprising a stacking fault that forms the bottom surface of the recess, wherein
the silicon carbide epitaxial substrate does not have a downfall contiguous to the stacking fault.

### (Supplementary Note 9)

The silicon carbide epitaxial substrate according to supplementary note 1 or 2, wherein a thickness of the silicon carbide epitaxial layer in the direction perpendicular to the main surface is 7 μm or more and 15 μm or less.

### (Supplementary Note 10)

The silicon carbide epitaxial substrate according to supplementary note 1 or 2, wherein a diameter of the main surface is 100 mm or more.

### (Supplementary Note 11)

A method of manufacturing a silicon carbide semiconductor device, the method comprising:
preparing the silicon carbide epitaxial substrate according to supplementary note 1 or 2; and
processing the silicon carbide epitaxial substrate.

The embodiments and examples disclosed herein are illustrative and non-restrictive in any respect. The scope of the present invention is defined by the terms of the claims, rather than the embodiments described above, and is intended to include any modifications within the scope and meaning equivalent to the terms of the claims.

### REFERENCE SIGNS LIST

1: first main surface; 2: second main surface; 3: orientation flat; 4: arc-shaped portion; 5: outer peripheral edge; 6: fourth main surface; 9: third main surface; 20: stacking fault; 21: apex; 22: first bottom side portion; 23: first side portion; 24: second side portion; 25: top surface portion; 26: bottom surface portion; 27: first side surface portion; 28: starting point; 29: recess; 30: silicon carbide substrate; 40: silicon carbide epitaxial layer; 41: buffer layer; 42: drift layer; 43: transition layer; 53: side wall surface; 54: bottom wall surface; 56: trench; 62: second bottom side portion; 63: third side portion; 64: fourth side portion; 66: third side surface portion; 67: second side surface portion; 100: silicon carbide epitaxial substrate; 101: first direction; 102: second direction; 103: third direction; 104: fourth direction; 113: body region; 114: source region; 115: gate insulating film; 116: source electrode; 117: mask; 118: contact region; 119: source wiring; 123: drain electrode; 126: interlayer insulating film; 127: gate electrode; 201: reaction chamber; 202: stage; 203: heating element; 204: quartz tube; 205: inner wall surface; 207: gas introduction port; 208: gas discharging port; 209: rotation shaft; 210: susceptor; 231: first gas supply unit; 232: second gas supply unit; 233: third gas supply unit; 234: fourth gas supply unit; 235: gas supply unit; 241: first gas flow rate control unit; 242: second gas flow rate control unit; 243: third gas flow rate control unit; 244: fourth gas flow rate control unit; 245: control unit; 300: manufacturing apparatus; 400: silicon carbide semiconductor device; A1: first length; A2: second length; B: width; C1: first ratio; C2: second ratio; D: depth; H: thickness; P1: first time point; P2: second time point; P3: third time point; P4: fourth time point; W: maximum diameter; θ: off angle.

1. A silicon carbide epitaxial substrate comprising:
a silicon carbide substrate; and
a silicon carbide epitaxial layer located on the silicon carbide substrate and having a main surface, wherein
a recess is formed in the main surface,
as viewed in a direction perpendicular to the main surface, an outer shape of the recess is a triangular shape,
a depth of the recess in the direction perpendicular to the main surface is 100 nm or more,
a length of the recess in a direction obtained by projecting a <11-20> direction onto the main surface is 80 μm or less,
an area density of the recess in the main surface is 0.1/cm² or less, and
a polytype of silicon carbide of a bottom surface of the recess is different from a polytype of silicon carbide of the silicon carbide epitaxial layer.

2. The silicon carbide epitaxial substrate according to claim 1, wherein the depth of the recess in the direction perpendicular to the main surface is 140 nm or less.

3. The silicon carbide epitaxial substrate according to claim 1, wherein the length of the recess in the direction obtained by projecting the <11-20> direction onto the main surface is 15 μm or more.

4. The silicon carbide epitaxial substrate according to claim 1, wherein the polytype of the silicon carbide of the bottom surface of the recess is 3C.

5. The silicon carbide epitaxial substrate according to claim 1, wherein the polytype of the silicon carbide of the silicon carbide epitaxial layer is 4H.

6. The silicon carbide epitaxial substrate according to claim 1, wherein the area density of the recess in the main surface is 0.005/cm² or more.

7. The silicon carbide epitaxial substrate according to claim 1, wherein the main surface is a plane inclined with respect to a (000-1) plane.

8. The silicon carbide epitaxial substrate according to claim 1, further comprising a stacking fault that forms the bottom surface of the recess, wherein
the silicon carbide epitaxial substrate does not have a downfall contiguous to the stacking fault.

9. The silicon carbide epitaxial substrate according to claim 1, wherein a thickness of the silicon carbide epitaxial layer in the direction perpendicular to the main surface is 7 μm or more and 15 μm or less.

10. The silicon carbide epitaxial substrate according to claim 1, wherein a diameter of the main surface is 100 mm or more.

11. A method of manufacturing a silicon carbide semiconductor device, the method comprising:
preparing the silicon carbide epitaxial substrate according to claim 1; and
processing the silicon carbide epitaxial substrate.
